(19) United States
(12) Patent Application Publication
(10) Pub. No.: US 2012/0106038 A1
(43) Pub. Date: May 3, 2012

(54) ELECTRONIC DEVICE AND KEY ASSEMBLY THEREOF

(75) Inventors: HE-HUI YANG, Shenzhen City (CN); YU-GUO GAO, Shenzhen City (CN); KAI-KUEI WU, Tu-Cheng (TW); KUN-CHIH HSIEH, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/039,329

(22) Filed: Mar. 3, 2011

(30) Foreign Application Priority Data
Oct. 28, 2010 (CN) 201010523119.9

(51) Int. Cl. H05K 5/02; H01H 13/76

(52) U.S. Cl. 361/679.01; 200/5 A

(57) ABSTRACT

An electronic device includes a casing defining a through opening, and a key assembly received in the opening. The key assembly includes a number of keys, an elastic strip corresponding to the number of keys, and two fixing members. The two fixing members fix the key assembly on the casing. Each fixing member includes a connection member, a pivot receiver connected to the connection member and a pivot extending through the pivot receiver fixed to the casing. A key assembly for an electronic device is also provided.

### BACKGROUND

1. Technical Field

The present disclosure relates to an electronic device and a key assembly thereof.

2. Description of Related Art

A key assembly equipped on an electronic device often includes one or more keys, one or more rubber blocks each corresponding to one of the one or more keys, and one or more pivots for fixing the one or more keys to the electronic device. Each pivot is allocated right under a corresponding key, thus when a user depresses the central portion of the key, the pivot resists the central portion of the key, the user may get weak resistance or even no resistance from the key. That is, a blind feeling area exists around the central part of the key. Thus the user may press the key repeatedly which causes unexpected operations.

Therefore, what is needed is an electronic device and a key assembly thereof alleviating the limitations described above.

### BRIEF DESCRIPTION OF THE DRAWINGS

The components in the drawings are not necessarily drawn to scale, the emphasis instead being placed upon clearly illustrating the principles of an electronic device and a key assembly thereof. Moreover, in the drawings, like reference numerals designate corresponding parts throughout the several views.

FIG. 1 is an isometric view of an exemplary embodiment of an electronic device and a key assembly thereof.

FIG. 2 is a partial, exploded view of the electronic device of FIG. 1.

FIG. 3 is a partial, exploded view of the electronic device of FIG. 1, viewed from another perspective.

FIG. 4 is an isometric view of the key assembly of FIG. 1.

### DETAILED DESCRIPTION

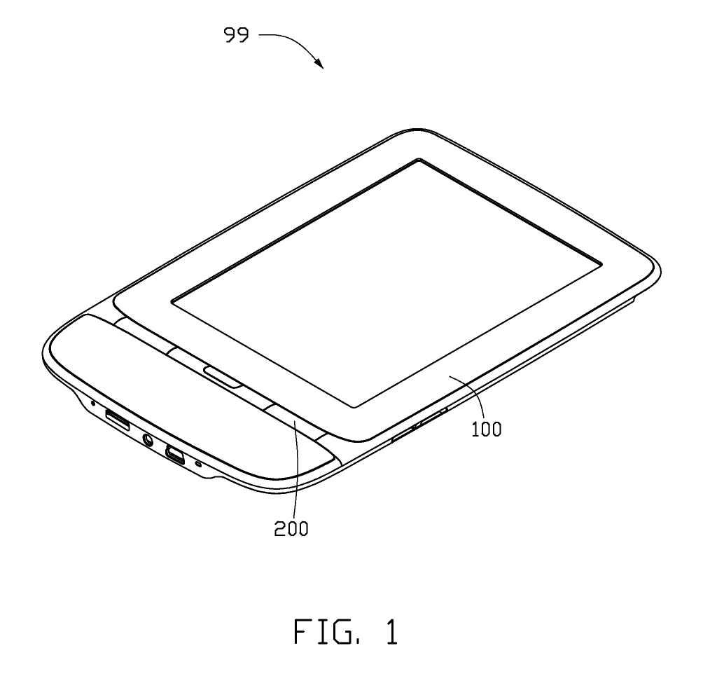

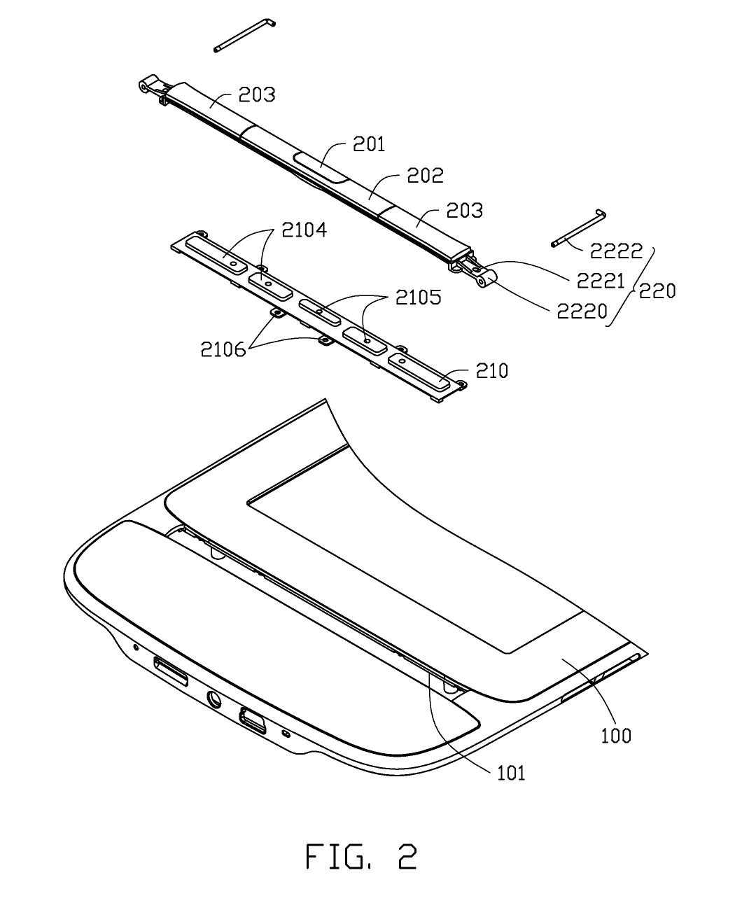

Referring to FIGS. 1 and 2, an electronic device 99 is disclosed as an exemplary embodiment. The electronic device 99 includes a casing 100 defining a through opening 101 and including a key assembly 200 received in the through opening 101. The key assembly 200 includes a number of keys, an elastic strip 210, and two fixing members 220. The elastic strip 210 may be integrally formed and is fixed on the casing 100. The elastic strip 210 is corresponding to the number of keys. The two fixing members 220 are used for fixing the keys to the casing 100. In the embodiment, the elastic strip 210 is made of rubber, the keys in the key assembly 200 include a first key 201, a second key 202, and two third keys 203 with the second key 202 spaced between them. The electronic device 99 can be an electronic reader, a music player, or a mobile phone. The first key 201 can be a home key. The second key 202 can be a page down key, and the two third keys 203 can be page up keys. The first, second and third keys 201, 202, 203 can be used for actuating corresponding page function. The numbers and functions of keys may vary according to actual need in alternative embodiments.

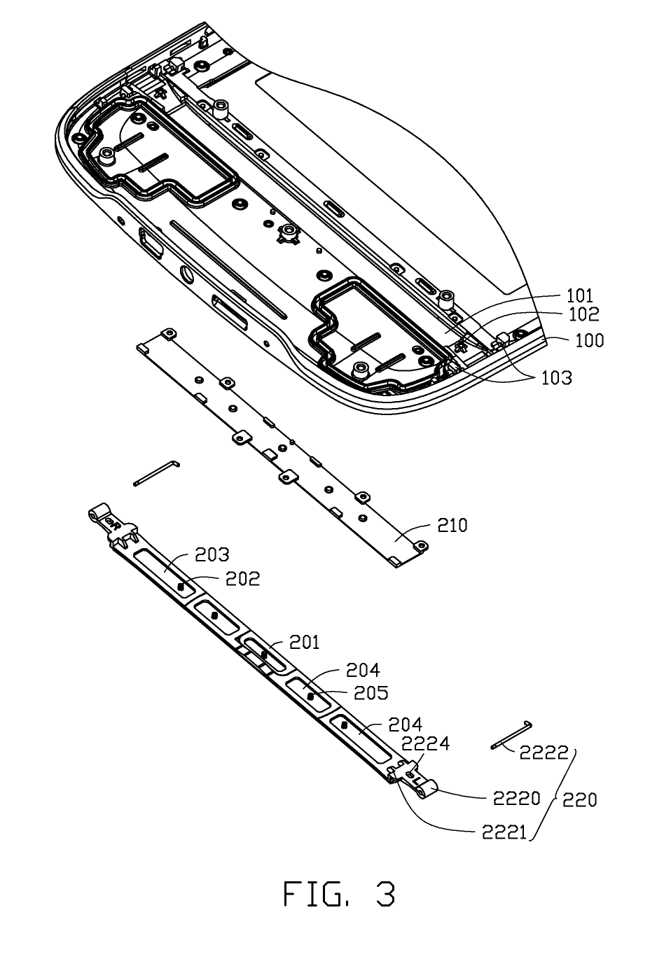

Referring to FIGS. 2 and 3, each of the first, second, and third keys 201, 202, and 203 define a groove 204 in its inner side. A protrusion 205 protrudes from the bottom of the groove 204. The rubber strip 210 is elongate strip shaped and includes a number of blocks 2104 corresponding to the grooves 204, and a number of recesses 2105 corresponding to the protrusions 205. The blocks 2104 protrude from the rubber strip 210 and oppose the grooves 204, and the recesses 2105 are defined in the block 2104. A number of lugs 2106 protrude outwardly from two edges of the rubber strip 210. The number of lugs 2106 are fixed on the casing 100 via screws (not shown), thus fixing the rubber strip 210 in the casing 100.

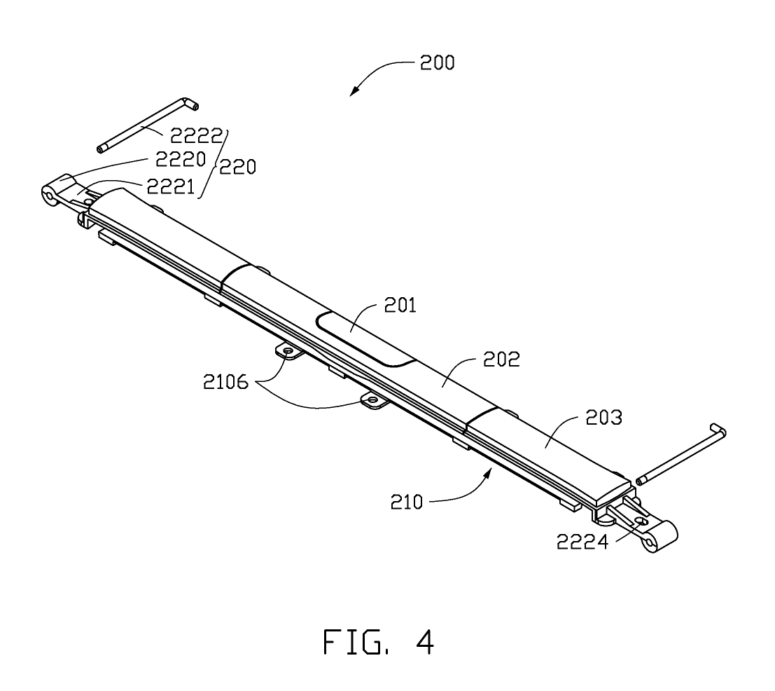

Referring to FIGS. 3 and 4, each of the two fixing members 220 includes a connection member 2221, a pivot receiver 2220 connected to the connection member 2221 and a pivot 2222 extending through the pivot receiver 2220 fixed on the casing 100. The connection member 2221 defines a fixing hole 2224 together with the number of lugs 2106, fixing the rubber strip 210 on the casing 100. Two ends of the connection member 2221 are respectively connected to the third key 203 and the pivot receiver 2220. The pivot receiver 2220 defines a through hole (not labeled) extending through near the pivot 2222.

Two positioning members 102 and two fixing members 103 protrude from the inner surface of the casing 100 and both are allocated on opposite sides of the through opening 101. The positioning member 102 extends through the fixing hole 2224 of the fixing member 220, and the pivot 2222 extends through the holes (not labeled) of the fixing member 103 and the pivot receiver 2220, thus cooperatively fixing the key assembly 200 on the casing 100.

In assembly, the block 2104 of the rubber strip 210 is aligned with the groove 204, and the recess 2105 is aligned with the protrusion 205 to assemble the rubber strip 210 with the key assembly 200. The sub-assembly of the rubber strip 210 and the key assembly 200 are then connected to the casing from the inner side, with the rubber strip 210. The fixing member 220 of the key assembly 200 is received within the through opening 101 and the keys of the key assembly 200 protrude out of the through opening 101. Two ends of the pivot 2222 are then received in the holes (not labeled) of the fixing members 103 to fix the fixing member 220 to the casing 100. Screws (not shown) are then inserted through the lugs 2106 and the though holes (not labeled) defined in the casing 100, to fix the rubber strip 210 in the casing 100.

In the embodiment, the two pivots 2222 for fixing the key assembly 200 on the casing 100 are allocated at the two ends of the key assembly 200. Each of the number of keys has a better resilient force after being depressed. Furthermore, the rubber strip 210 corresponding to the number of keys also applies a resilient force to the depressed key. Thus, when a user depresses on any portion of a key, the user gets better tactile resistance.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. An electronic device comprising:
a casing defining a through opening; and
a key assembly received in the opening, comprising:
a plurality of keys;
an elastic strip corresponding to the plurality of keys; and
two fixing members fixing the key assembly on the casing, each fixing member comprising a connection member, a pivot receiver connected to the connection member and a pivot extending through the pivot receiver and fixed to the casing.

2. The electronic device as described in claim 1, wherein the elastic strip is made of rubber.

3. The electronic device as described in claim 2, wherein each of the plurality of keys defines a groove in an inner side thereof, each of the groove comprises a protrusion protruding from a bottom thereof, the elastic strip comprises a plurality of blocks corresponding to the grooves, and defines a plurality of recesses corresponding to the protrusions.

4. The electronic device as described in claim 1, wherein a plurality of lugs protrude outwardly from two edges of the elastic strip and are fixed on the casing.

5. The electronic device as described in claim 4, wherein the connection member defines a fixing hole for, together with the number of lugs, fixing the elastic strip on the casing.

6. The electronic device as described in claim 1, wherein two positioning members and two fixing members protrude from an inner surface of the casing and both are allocated on opposite sides of the through opening.

7. The electronic device as described in claim 1, wherein the plurality of keys is configured for paging up and down.

8. A key assembly for an electronic device, comprising:
a plurality of keys;
an elastic strip corresponding to the plurality of keys; and
two fixing members fixing the key assembly on the electronic device, each fixing member comprising a connection member, a pivot receiver connected to the connection member and a pivot extending through the pivot receiver and fixed to the electronic device.

9. The key assembly described in claim 8, wherein the elastic strip is made of rubber.

10. The key assembly as described in claim 9, wherein each of the plurality of keys define a groove in an inner side thereof, each of the groove comprises a protrusion protruding from a bottom thereof, the elastic strip comprises a plurality of blocks corresponding to the grooves, and defines a plurality of recesses corresponding to the protrusions.

11. The key assembly as described in claim 8, wherein a plurality of lugs protrudes outwardly from two edges of the elastic strip and are fixed on the electronic device.

12. The key assembly as described in claim 11, wherein the connection member defines a fixing hole for, together with the number of lugs, fixing the elastic strip on the electronic device.

13. The key assembly as described in claim 9, wherein the plurality of keys is configured for paging up and down.
